(19) United States
(12) Patent Application Publication
(10) Pub. No.: US 2021/0018996 A1
(43) Pub. Date: Jan. 21, 2021

(54) HYBRID STYLUS AND TOUCH INPUT DEVICE COMMUNICATING WITH SAME

(71) Applicant: HiDeep Inc., Seongnam-si, Gyeonggi-do (KR)

(72) Inventor: Youngmin LEE, Seongnam-si, Gyeonggi-do (KR)

(73) Assignee: HiDeep Inc., Seongnam-si, Gyeonggi-do (KR)

(21) Appl. No.: 17/044,506

(22) PCT Filed: Apr. 18, 2019
(86) PCT No.: PCT/KR2019/004702

§ 371 Date: Oct. 1, 2020

(30) Foreign Application Priority Data
Apr. 26, 2018 (KR) 10-2018-0048205

(51) Int. Cl. G06F 3/0354; G01R 31/382; G06F 3/044; G06F 3/038; G06F 1/28

(52) U.S. Cl. CPC G06F 3/03545; G01R 31/382; G06F 1/28; G06F 3/038; G06F 3/044

(57) ABSTRACT

A hybrid stylus communicating with a touch input device according to an embodiment of the present invention may include a conductive tip that forms a capacitance with at least one of a plurality of electrodes in the touch input device, a first mode operation unit that operates with the touch input device based on a predetermined power, a second mode operation unit that operates by using a change in capacitance for at least one of the plurality of electrodes in the touch input device by the conductive tip, a switch configured to connect the conductive tip to the first mode operation unit or the second mode operation unit, a power supply unit that provides the predetermined power to the first mode operation unit, a communication unit that transmits mode conversion information for converting an operation mode of the touch input device to the touch input device, and a controller that checks the remaining amount of the power to control the switch to connect the conductive tip to the first mode operation unit when a remaining amount of the power is greater than or equal to a predetermined threshold value and to control the switch to connect the conductive tip to the second mode operation unit when the remaining amount of the power is less than the predetermined threshold, and controls the communication unit to transmit the mode conversion information to the touch input device.

### TECHNICAL FIELD

The present invention relates to a hybrid stylus and a touch input device communicating with the hybrid stylus, and more specifically, to a hybrid stylus capable of driving by switching mode from active mode to passive mode when a battery of the hybrid stylus runs out, and a touch input device communicating the hybrid stylus.

### BACKGROUND ART

Various types of input devices are used to manipulate a computing system. For example, input devices such as buttons, keys, joysticks, and touch screens are used. Due to an easy and simple manipulation of the touch screen, the use of the touch screen is increasing when manipulating the computing system.

The touch screen may configure a touch surface of a touch input device including a touch sensor panel, which may be a transparent panel having a touch-sensitive surface. Such a touch input device may be attached to a front surface of a display screen so that the touch-sensitive surface covers a visible surface of the display screen. The user may manipulate the computing system by simply touching the touch screen with a finger or a stylus. In general, the computing system may recognize a touch and a touch position on the touch screen and interpret the touch to perform an operation accordingly.

An advantage of a touch input method is that portability is guaranteed, there is almost no breakdown, and it very intuitive than the conventional input method represented by a keyboard and mouse. However, it is true that the touch input method, as a tool that consumes content, is superior to other input methods, but the touch input method, as a tool for producing content, lacks the detail, speed, and convenience of input. To overcome this, the use of a pen, which is a tool that humans have used for thousands of years, is emerging as an alternative, instead of fingers as a tool for touch input. A pen used in electronic devices is commonly referred to as a stylus.

Meanwhile, a conventional stylus is classified into a passive stylus and an active stylus according to an operating principle. The passive stylus uses the same principle as a principle of sensing a finger touch on a general touch screen and requires only a conductive tip without a separate battery, and thus the passive stylus has an advantage in price competitiveness, but has a disadvantage of being susceptible to noise due to its fine signal sensing level. While the active stylus has the advantage of excellent writing/drawing performance, being a method suitable for implementing additional functions such as hover, pen pressure, etc., and transmitting various types of information through wireless communication with the touch input device, the active stylus has a disadvantage that the price is relatively expensive because a separate battery needs to be implemented.

Meanwhile, while the active stylus performs (e.g., handwriting) a command according to a user command together with the touch input device, if the battery of the stylus runs out, the stylus no longer operates and the touch input system stops. In that case, there is a problem that writing is also cut off, and driving the system again wastes time and cost, and causes inconvenience to the user.

### DISCLOSURE OF THE INVENTION

### Technical Problem

The present invention has been derived to solve the problems described above, and the hybrid stylus according to the present invention is a combination of an additional function implementation, which is an advantage of an active stylus, and a feature that does not require a separate battery, which is an advantage of a passive stylus, and an object thereof is to allow switching from active stylus mode to passive stylus mode to be automatically performed.

The present invention has been derived to solve the problems described above, and an object thereof is to allow an operation with a touch input device to be continuously performed by performing a mode change even when the battery of the stylus runs out.

### Technical Solution

A hybrid stylus communicating with a touch input device according to an embodiment of the present invention may include a conductive tip that forms a capacitance with at least one of a plurality of electrodes in the touch input device, a first mode operation unit that operates with the touch input device based on a predetermined power, a second mode operation unit that operates by using a change in capacitance for at least one of the plurality of electrodes in the touch input device by the conductive tip, a switch configured to connect the conductive tip to the first mode operation unit or the second mode operation unit, a power supply unit that provides the predetermined power to the first mode operation unit, a communication unit that transmits mode conversion information for converting an operation mode of the touch input device to the touch input device, and a controller that checks the remaining amount of the power to control the switch to connect the conductive tip to the first mode operation unit when a remaining amount of the power is greater than or equal to a predetermined threshold value and to control the switch to connect the conductive tip to the second mode operation unit when the remaining amount of the power is less than the predetermined threshold, and controls the communication unit to transmit the mode conversion information to the touch input device.

A touch input device communicating with a hybrid stylus according to another embodiment of the present invention may include a first mode operation unit that operates in a first mode together with the hybrid stylus operating based on a predetermined power, a second mode operation unit that operates in a second mode by using a change in capacitance for at least one of a plurality of electrodes in the touch input device by the hybrid stylus, a communication unit that receives mode conversion information from the hybrid stylus, and a control unit that controls to operate in the first mode or controls to operate in the second mode based on the mode conversion information for operating in the first mode or in the second mode.

A hybrid stylus communicating with a touch input device according to still another embodiment of the present invention may include a conductive tip that forms a capacitance with at least one of a plurality of electrodes in the touch input device, a first mode operation unit that operates in a first mode with the touch input device based on a predetermined power, a second mode operation unit that operates in a second mode using a change in capacitance for at least one of the plurality of electrodes in the touch input device by the conductive tip, a switch configured to connect the conductive tip to the first mode operation unit or the second mode operation unit, a power supply unit that provides the predetermined power to the first mode operation unit, a communication unit that transmits information on a remaining amount of the power to the touch input device and receives mode conversion information from the touch input device, and

a controller that arranges a position of the switch to the first mode operation unit or the second mode operation unit based on the mode conversion information.

A touch input device communicating with a hybrid stylus according to still yet another embodiment of the present invention may include a first mode operation unit that operates in a first mode together with the hybrid stylus operating based on a predetermined power, a second mode operation unit that operates in a second mode by using a change in capacitance for at least one of a plurality of electrodes in the touch input device by the hybrid stylus, a communication unit that receives information on a remaining amount of a power of the hybrid stylus from the hybrid stylus and transmits mode conversion information to the hybrid stylus, and a control unit that checks information on the remaining amount of the power to control to operate in the first mode when the remaining amount of the power is greater than or equal to a predetermined threshold value and to operate in the second mode when the remaining amount of the power is less than the predetermined threshold value, and controls the communication unit to transmit the mode conversion information for operating in the first mode or the second mode.

A hybrid stylus communicating with a touch input device according to still yet another embodiment of the present invention may include a conductive tip that forms a capacitance with at least one of a plurality of electrodes in the touch input device, a first mode operation unit that generates a response signal independent from a driving signal input from the touch input device in response to the driving signal and transmits the response signal to the conductive tip, a power supply unit that provides a predetermined power to the first mode operation unit, and a communication unit that transmits information on a remaining amount of the power to the touch input device.

A touch input device communicating with a hybrid stylus according to still yet another embodiment of the present invention may include a first mode operation unit that is independent of a driving signal for driving the hybrid stylus and operates in a first mode based on a response signal generated from the hybrid stylus in response to the driving signal, a communication unit that receives information on a remaining amount of a power of the hybrid stylus from the hybrid stylus, and a control unit that checks the remaining amount of the power and controls to operate in the first mode when the remaining amount of the power is greater than or equal to a predetermined threshold value and not to transmit the driving signal to the hybrid stylus when the remaining amount of the power is less than the predetermined threshold value.

A hybrid stylus communicating with a touch input device according to still yet another embodiment of the present invention may include a conductive tip that forms a capacitance with at least one of a plurality of electrodes in the touch input device, a first mode operation unit that operates with the touch input device based on a predetermined power, a second mode operation unit that operates by using a change in capacitance for at least one of the plurality of electrodes in the touch input device by the conductive tip, a switch configured to connect the conductive tip to the first mode operation unit or the second mode operation unit, a power supply unit that provides the predetermined power to the first mode operation unit, a communication unit that receives mode conversion information for operating in the first mode or operating in the second mode from the touch input device, and a controller that arranges a position of the switch to the first mode operation unit or the second mode operation unit based on the mode conversion information.

A touch input device communicating with a hybrid stylus according to still yet another embodiment of the present invention may include a first mode operation unit that operates in a first mode together with the hybrid stylus operating based on a predetermined power, a second mode operation unit that operates in a second mode by using a change in capacitance for at least one of the plurality of electrodes in the touch input device by the conductive tip, a button unit that receives a user input for changing an operation mode with the hybrid stylus, a communication unit that transmits operation mode conversion information according to the user input to the hybrid stylus, and a control unit that controls to operate in the first mode or the second mode based on the user input.

A hybrid stylus communicating with a touch input device according to still yet another embodiment of the present invention may include a conductive tip that forms a capacitance with at least one of a plurality of electrodes in the touch input device and a first mode operation unit that generates a response signal independent from a driving signal input from the touch input device in response to the driving signal and transmits the response signal to the conductive tip.

A touch input device communicating with a hybrid stylus according to still yet another embodiment of the present invention may include a first mode operation unit that is independent of a driving signal for driving the hybrid stylus and operates in a first mode based on a response signal generated from the hybrid stylus in response to the driving signal, a button unit that receives a user input for changing an operation mode with the hybrid stylus, and a control unit that controls to operate in the first mode or not to transmit the driving signal to the hybrid stylus, based on the user input.

A hybrid stylus communicating with a touch input device according to still yet another embodiment of the present invention may include a conductive tip that forms a capacitance with at least one of a plurality of electrodes in the touch input device, a first mode operation unit that operates with the touch input device based on a predetermined power, a second mode operation unit that operates by using a change in capacitance for at least one of the plurality of electrodes in the touch input device by the conductive tip, a switch configured to connect the conductive tip to the first mode operation unit or the second mode operation unit, a power supply unit that provides the predetermined power to the first mode operation unit, a user input receiving unit that receives a user input for converting an operation mode with the touch input device, a communication unit that transmits operation mode conversion information according to the user input to the touch input device, and a controller that arranges a position of the switch to the first mode operation unit or the second mode operation unit based on the mode conversion information.

A touch input device communicating with a hybrid stylus according to still yet another embodiment of the present invention may include a first mode operation unit that operates in a first mode together with the hybrid stylus operating based on a predetermined power, a second mode operation unit that operates in a second mode by using a change in capacitance for at least one of the plurality of electrodes in the touch input device by the conductive tip, a communication unit that receives mode conversion information for operating in the first mode or operating in the second mode according to a user input from the hybrid stylus, and a control unit that controls to operate in the first mode or to operate in the second mode based on the mode conversion information.

### Advantageous Effects

According to an embodiment of the present invention, switching from active stylus mode to passive stylus mode may be performed automatically by combining an additional function implementation, which is an advantage of an active stylus, and a feature that does not require a separate battery, which is an advantage of a passive stylus.

According to an embodiment of the present invention, even when the battery of the stylus runs out, time and cost may be saved by continuously performing an operation with the touch input device in a switched mode.

### BRIEF DESCRIPTION OF THE DRAWINGS

FIGS. 1A to 1D are diagrams referenced to illustrate an operation system of a touch input device according to an embodiment of the present invention.

FIGS. 2A to 2C are diagrams referenced to describe data transmission and reception between a touch input device and a hybrid stylus according to an embodiment of the present invention.

FIG. 3 is a diagram referenced to describe data transmission and reception between a touch input device and a hybrid stylus according to another embodiment of the present invention.

FIGS. 4A and 4B are diagrams for explaining a first mode operation between the hybrid stylus and the touch input device according to the embodiment of the present invention.

### MODE FOR CARRYING OUT THE INVENTION

For a detailed description of the present invention to be described later, reference is made to the accompanying drawings, which illustrate specific embodiments in which the present invention may be practiced. These embodiments are described in detail sufficient to enable a person skilled in the art to practice the present invention. It is to be understood that the various embodiments of the present invention are different from each other, but need not be mutually exclusive. For example, certain shapes, structures, and features described herein may be implemented in other embodiments without departing from the spirit and scope of the present invention in relation to one embodiment. In addition, it is to be understood that the location or arrangement of individual components within each disclosed embodiment may be changed without departing from the spirit and scope of the present invention. Accordingly, the detailed description to be described below is not intended to be taken in a limiting sense, and the scope of the present invention, if properly described, is limited only by the appended claims, along with all scopes equivalent to those claimed by the claims. Like reference numerals in the drawings refer to the same or similar functions over several aspects.

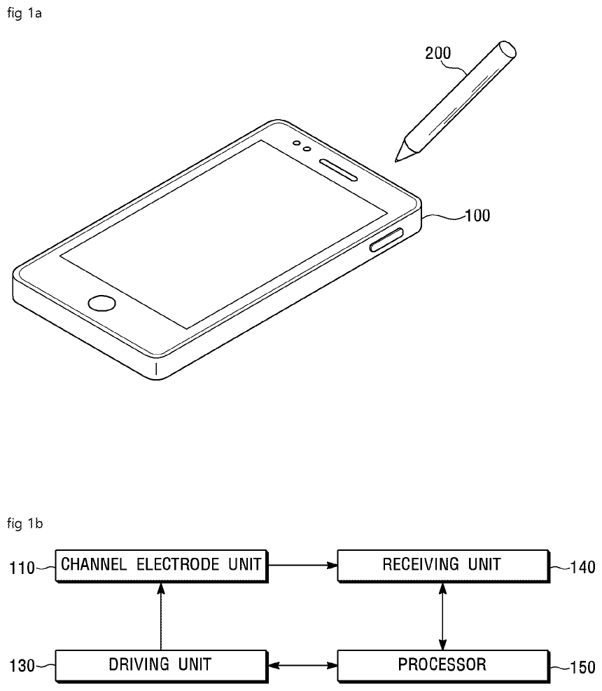

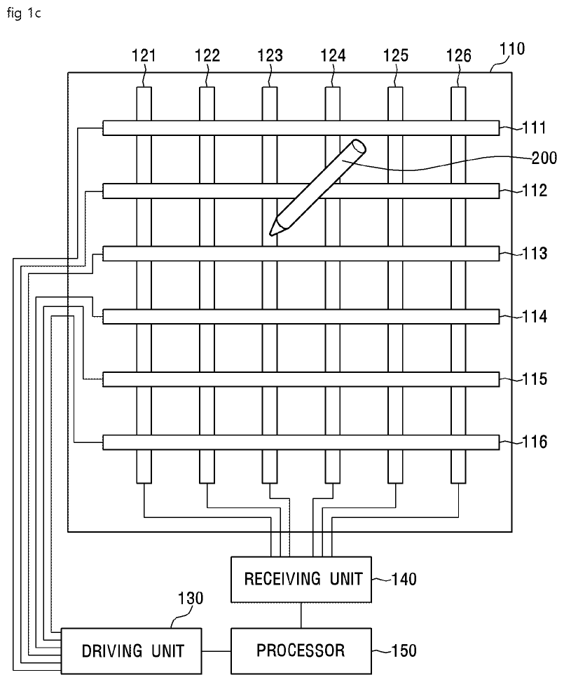

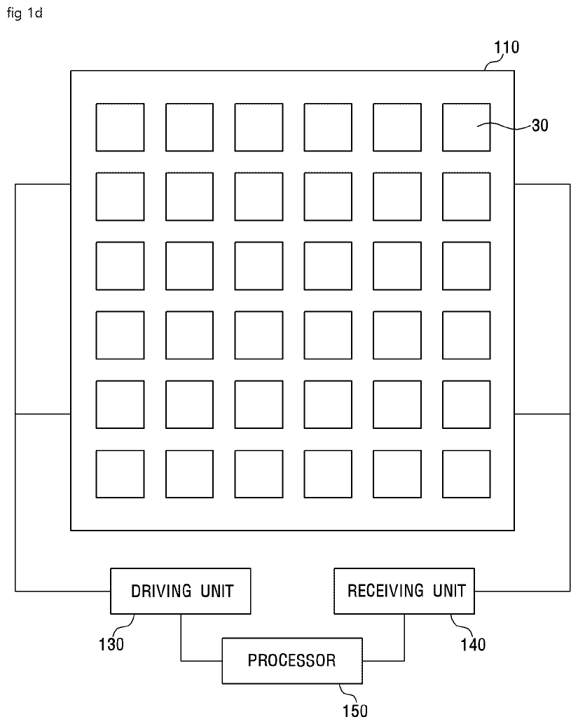

FIG. 1A is a diagram referenced to illustrate an operation system of a touch input device according to an embodiment of the present invention.

Referring to FIG. 1, the operation system of the touch input device may be configured with a touch input device 100 and a hybrid stylus 200.

The touch input device 100 determines a position of the hybrid stylus 200. The hybrid stylus 200 may operate in an active hybrid stylus mode 200A (hereinafter referred to as a first mode) or may operate in a passive hybrid stylus mode 200B (hereinafter referred to as a second mode) together with the touch input device 100. In the present invention, the first mode means that the hybrid stylus 200 operates with the touch input device 100 to determine the position of the hybrid stylus 200 by outputting a signal by itself using a built-in battery power, and the second mode means that the hybrid stylus 200 operates with the touch input device 100 to determine the position of the hybrid stylus 200 using a change in capacitance by a conductive tip without a separate battery power.

Specifically, when operating in the first mode that has its own power supply, the position of the hybrid stylus 200 on the touch input device 100 may be determined by operating in a synchronous manner or an asynchronous manner. According to an embodiment of the present invention, it may be implemented in a synchronous manner in which the hybrid stylus 200 receives a driving signal of the touch input device 100, generates a response signal independent from the driving signal input from the touch input device 100 in response to the driving signal, and transmits the response signal to the conductive tip to operate with the touch input device 100, or may be implemented, according to another embodiment, in an asynchronous manner in which the hybrid stylus 200 output its own signal even without the driving signal of the touch input device 100 to operate with the touch input device 100. On the other hand, when operating in the second mode that does not have its own power supply, the hybrid stylus 200 may operate by using a change in capacitance for at least one of the plurality of electrodes in the touch input device 100 by a conductive tip. In this case, in the present invention, the first mode or the second mode is defined as an operation mode between the touch input device 100 and the hybrid stylus 200.

Here, the touch input device 100 may be a touch pad, a touch screen, or an electronic device such as a laptop, mobile phone, smart phone, PMP, MP3 player, etc. having the touch pad or the touch screen.

Meanwhile, in the description of FIG. 1A, it is illustrated that one hybrid stylus 200 contacts the touch input device 100, but in implementation, a plurality of hybrid styli may connect one touch input device 100, and in this case, the touch input device 100 may sense the position of each of the plurality of hybrid styli.

FIGS. 1B to 1D are block diagrams illustrating a specific configuration of the touch input device 100 of FIG. 1A.

Referring to FIG. 1B, the touch input device 100 may be configured with a channel electrode unit 110, a driving unit 130, a receiving unit 140, and a processor 150.

The channel electrode unit 110 includes a plurality of electrodes as illustrated in FIGS. 1C and 1D. As illustrated in FIG. 1C, the channel electrode unit 110 may include a plurality of electrodes arranged in a matrix form. For example, the channel electrode unit 110 may include a plurality of first electrodes 111, 112, 113, 114, 115, and 116 arranged in a first direction and a plurality of second electrodes 121, 122, 123, 124, 125, and 126 arranged in a second direction perpendicular to the first direction. Here, the first electrodes and/or the second electrodes may be transparent electrodes, and may be made of an indium tin oxide (ITO) material.

The driving unit 130 generates a driving signal and provides the driving signal to all or part of the plurality of first electrodes in the channel electrode unit 110.

The receiving unit 140 receives a reception signal from all or part of the plurality of second electrodes in the channel electrode unit 100.

The processor 150 determines the position of the hybrid stylus 200 based on the received signal. Specifically, the processor 150 may determine the position of the hybrid stylus 200 based on a ratio between the reception signals received from each of the plurality of electrodes.

As described above, a predetermined value of capacitance Cm is generated at each intersection point of a first electrode TX and a second electrode RX, and when an object such as the hybrid stylus 200 approaches the touch input device 100, the value of such capacitance may change. In FIG. 1C, the capacitance may represent mutual capacitance (Cm). Such electrical characteristics may be sensed by the receiving unit 140 to sense the presence or absence of a touch and/or a touch position on the touch input device 100. For example, it is possible to sense the presence or absence of a touch and/or the position thereof on a surface of the touch input device 100 composed of a two-dimensional plane consisting of a first axis and a second axis.

More specifically, when a touch on the touch input device 100 occurs, the position of the touch in the second axis direction may be detected by detecting the first electrode TX to which the driving signal is applied. Similar to this, when the touch input device 100 is touched, the position of the touch in the direction of the first axis may be detected by detecting a change in capacitance from the reception signal received through the second electrode RX.

In the above description, an operation method of the touch input device 100 for sensing the touch position based on an amount of change in mutual capacitance between the first electrode TX and the second electrode RX has been described, but the present invention is not limited thereto. That is, as illustrated in FIG. 1D, it is possible to sense the touch position based on an amount of change in self capacitance.

The plurality of electrodes 30 may be arranged in a lattice shape at regular intervals as illustrated in FIG. 1D, but is not limited thereto.

A driving control signal generated by the processor 150 is transferred to the driving unit 130, and the driving unit 130 applies a driving signal to a preset touch electrode 30 at a predetermined time based on the driving control signal. In addition, a sensing control signal generated by the processor 150 is transferred to the receiving unit 140, and the receiving unit 140 receives a sensing signal from the preset touch electrode 30 at a predetermined time based on the sensing control signal. In this case, the sensing signal may be a signal for the amount of change in self capacitance formed on the touch electrode 30.

In this case, the presence or absence of a touch and/or a touch position to the touch electrode 30 is detected by the sensing signal sensed by the receiving unit 140. For example, since the coordinates of the touch electrode 30 are known in advance, the presence or absence of a touch of an object and/or the position thereof on the surface of the touch electrode 30 may be sensed.

In the description as above, the capacitive touch input device 100 has been described in detail, but, in the touch input device 100 according to an embodiment of the present invention, the channel electrode unit 110 for detecting the presence or absence of a touch and/or a touch position may be implemented by any touch sensing method such as a surface capacitance method other than the method described above, a projected capacitance method, a resistive film method, a surface acoustic wave (SAW) method, an infrared method, an optical imaging method, a dispersive signal technology, acoustic pulse recognition method, etc.

[symbol]

Meanwhile, according to an embodiment of the present invention, there is a need for the touch input device 100 to be driven in the first mode together with the hybrid stylus 200 and then to switch the mode to be driven in the second mode. For example, while the touch input device 100 operates in the first mode together with the hybrid stylus 200, if an amount of battery in the power supply unit 250 of the hybrid stylus 200 decreases or the battery completely falls below a threshold value to the extent that it is difficult to drive the hybrid stylus 200, it becomes difficult for the touch input device 100 to operate in the first mode any more. If the operation in the first mode is stopped and the entire system is stopped, an operation (e.g., handwriting) being performed by the user is cut off, making it uncomfortable. Accordingly, in this case, there is a need to perform a continuous operation regardless of the presence or absence of a battery by switching the mode to operate in the second mode.

Hereinafter, an operation between the touch input device 100 and the hybrid stylus 200 implemented according to this need will be described.

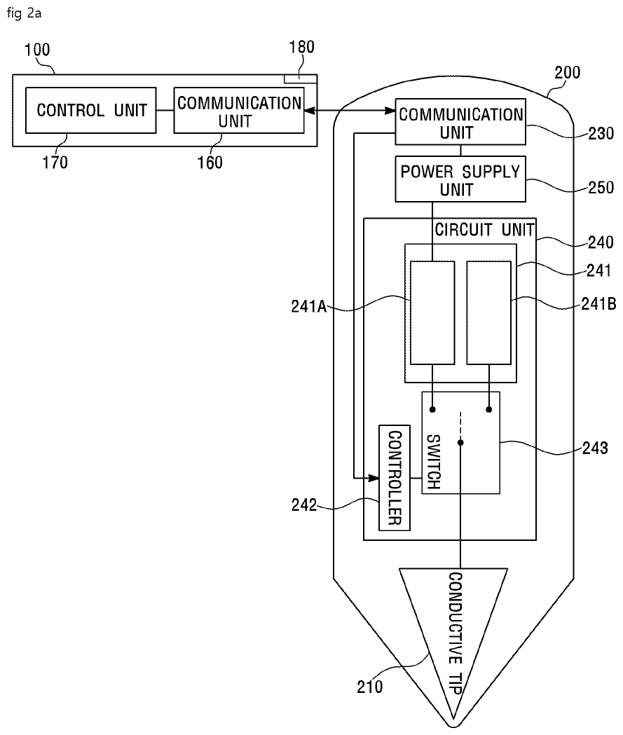

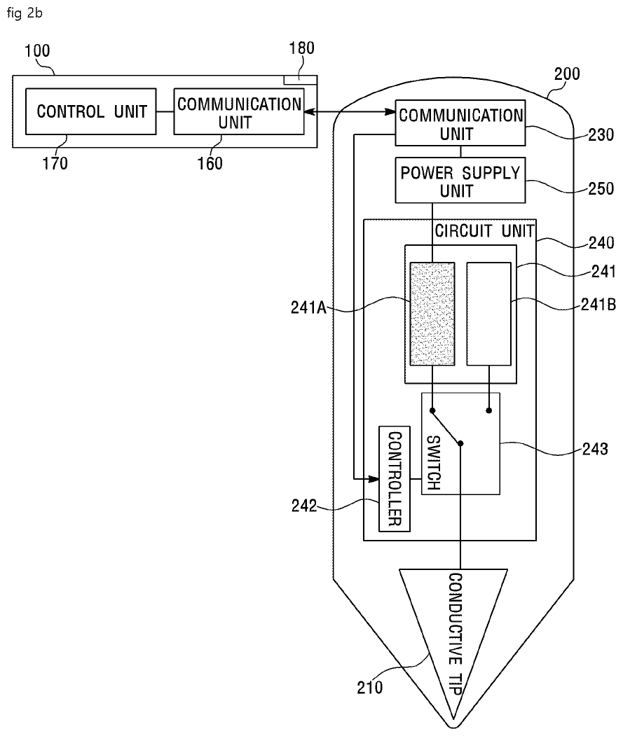

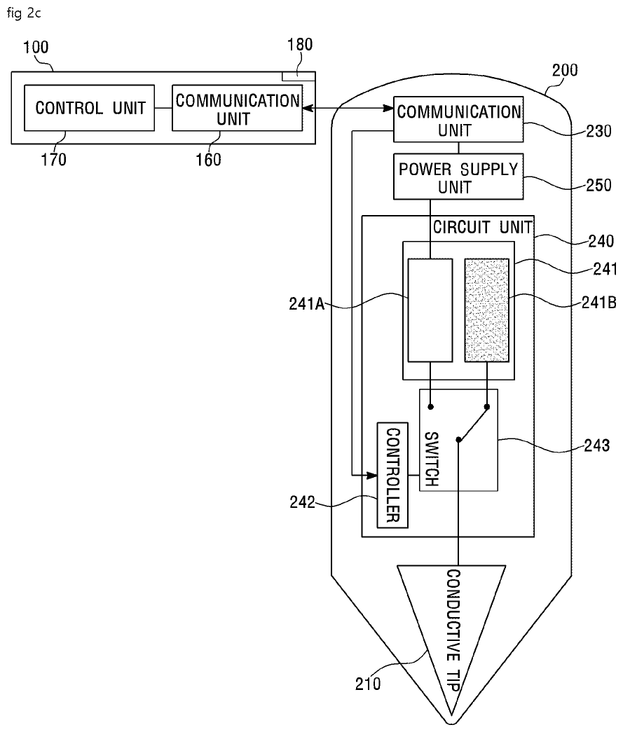

FIG. 2A is a diagram referenced to describe data transmission and reception between the touch input device 100 and the hybrid stylus 200 according to an embodiment of the present invention. In particular, FIG. 2A is referenced to describe a general configuration before the hybrid stylus 200 operates as a specific mode operation unit.

First, as illustrated in FIG. 2A, the touch input device 100 according to an embodiment of the present invention may include a communication unit 160, a control unit 170, and a button unit 180.

The communication unit 160 may perform data transmission and reception with the hybrid stylus 200. Depending on the embodiments, the operation of the touch input device 100 may be controlled by receiving a control command from the hybrid stylus 200, or the operation of the hybrid stylus 200 may be controlled by transmitting the control command to the hybrid stylus 200. Depending on the embodiments, two-way communication or only one-way communication may be implemented.

The control unit 170 may control to operate in the first mode together with the hybrid stylus 200 through the communication unit 160, or prepare for conversion to the second mode different from the first mode, and control to operate in the second mode together with the hybrid stylus 200. The controller 920 may be a main processor or an application processor.

The button unit 180 receives a user input for changing the operation mode with the hybrid stylus 200. The button unit 180 may be implemented on a touch screen or housing, in the form of an icon, or as a toggle button.

Meanwhile, as illustrated in FIG. 2A, the hybrid stylus 200 according to the embodiment of the present invention may include a conductive tip 210, a communication unit 230, a power supply unit 250, and a circuit unit 240, and the circuit unit 240 may include a mode operation unit 241 implemented as a first mode operation unit 241A and a second mode operation unit 241B, a controller 242, and a switch 243.

The conductive tip 210 forms a capacitance with at least one of a plurality of electrodes in the touch input device 100. This conductive tip 210 may be formed of a metallic tip, for example. In addition, the conductive tip 210 may be present inside a non-conductive material or a part of the conductive tip 210 may be exposed to the outside. In addition, the conductive tip 210 may further include an insulating portion preventing direct contact with the outside in order to soften feeling of writing during use.

In addition, when it operates in the first mode, the conductive tip 210 may receive a trigger signal (or an excitation signal) from the touch input device 100. Here, the trigger signal is a signal having a preset frequency and may have the same frequency as the driving signal.

The communication unit 230 may perform data transmission and reception data with the touch input device 100. Depending on the embodiments, the operation of the hybrid stylus 200 may be controlled by receiving a control command from the touch input device 100, or the operation of the touch input device 100 may also be controlled by transmitting the control command to the touch input device 100. Depending on the embodiments, it may be implemented in such a way that two-way communication is performed or only one-way communication is possible.

The mode operation unit 241 may include the first mode operation unit 241A operating in the first mode together with the touch input device 100 and the second mode operation unit 241B operating in the second mode together with the touch input device 100. The first mode operation unit 241A and the second mode operation unit 241B may be implemented as separate physical circuits, respectively, according to one embodiment, and are based on the same physical circuit, but may be processed differently only in software according to another embodiment.

The controller 242 may arrange the position of the switch 243 to operate in the first mode together with the touch input device 100 through the communication unit 230, or prepare for conversion to the second mode different from the first mode, and arrange the position of the switch 243 to operate in the second mode together with the touch input device 100.

The switch 243 is configured to connect the conductive tip 210 to the first mode operation unit 241A or the second mode operation unit 241B. For example, the switch 243 may be configured to connect the conductive tip 210 to the first mode operation unit 241A as illustrated in FIG. 2B, or may be configured to connect the conductive tip 210 to the second mode operation unit 241B as illustrated in FIG. 2C.

The power supply unit 250 may provide power to the circuit unit 240. Specifically, when the hybrid stylus 200 operates as the first mode operation unit 241A, power may be provided to the first mode operation unit 241A.

In the configuration of the touch input device 100 and/or the hybrid stylus 200 of FIG. 2A described above, all or a part of the configuration may be deleted, another component may be added, or modification may be made thereto.

FIG. 2B is a configuration diagram of the circuit unit 240 when the hybrid stylus 200 operates as the first mode operation unit 241A.

The circuit unit 240 generates a response signal having a preset frequency and provides the response signal to the conductive tip 210. Specifically, the first mode operation unit 241A may generate a response signal of a specific frequency generated by an internal device according to the power supplied from the power supply unit 250. For example, a modified response signal is generated by inverting the frequency or changing the phase of the driving signal, or changing a voltage level of the driving signal. In addition, the first mode operation unit 241A may provide the generated response signal to the conductive tip 210. Here, the response signal becomes an electric signal for measuring a contact position of the hybrid stylus 200 to the touch input device 100.

In addition, the first mode operation unit 241A may sense a pen pressure at the conductive tip 210 and change a frequency of the response signal according to the sensed pen pressure. In addition, the first mode operation unit 241A may sense the operation mode of the hybrid stylus 200, generate a response signal having a frequency corresponding to the sensed operation mode, and provide the response signal to the conductive tip 210.

In addition, if a trigger signal is sensed from the conductive tip 210, the first mode operation unit 241A may generate the response signal for a preset time. If the trigger signal is not sensed again within the preset time, the first mode operation unit 241A may stop generating the response signal. In addition, the first mode operation unit 241A may control each configuration within the hybrid stylus 200 so that the hybrid stylus 200 maintains a power saving state.

FIG. 2C is a configuration diagram of the circuit unit 240 when the hybrid stylus 200 operates as the second mode operation unit 241B.

According to an embodiment, as illustrated in FIG. 2C, the second mode operation unit 241B may be implemented with the same circuit as a circuit for varying capacitance for a conductive object such as a finger or a stylus. Alternatively, the second mode operation unit 241B may be implemented as a resonance circuit unit according to another embodiment. Here, the resonance circuit unit includes a parallel connection circuit composed of an inductor and a capacitor connected to the conductive tip 210. Specifically, the resonance circuit unit may resonate with a driving signal input from the touch input device 100.

Based on such a configuration of the touch input device 100 and the hybrid stylus 200 of FIGS. 2A to 2C, the touch input device 100 and the hybrid stylus 200 may operate as in the first to third embodiments below. Specifically, the touch input device 100 and the hybrid stylus 200 may operate differently depending on whether the subject transmitting the mode change command from the first mode to the second mode is the touch input device 100 or the hybrid stylus 200 and the touch input device 100 and the hybrid stylus 200 may operate differently depending on whether the mode change from the first mode to the second mode is automatically performed or manually performed according to a user input.

According to the first embodiment, when the hybrid stylus 200 and the touch input device 100 are operating in the first mode as illustrated in FIG. 2B, respectively, and then the hybrid stylus 200 generates a mode change command from the first mode to the second mode and transmits the mode change command to the touch input device 100, the hybrid stylus and the touch input device may operate in the second mode as illustrated in FIG. 2C, respectively.

Specifically, the controller 242 may check a remaining amount of a power of the power supply unit 250. This may be periodically checked for a predetermined number of times during a predetermined time interval, and information such as a predetermined time interval, a predetermined number of times, or a period may be preset and stored in a memory (not illustrated).

When it is determined that the checked remaining amount of the power is equal to or greater than a predetermined threshold value, the controller 242 may arrange the position of the switch 243 to the first mode operation unit 241A as illustrated in FIG. 2B. In contrast, when it is determined that the checked remaining amount of the power is less than the predetermined threshold value, the controller 242 may arrange the position of the switch 243 to the second mode operation unit 241B as illustrated in FIG. 2C. Information on the remaining amount of the power of the power supply unit 250 may be separately stored in a memory (not illustrated).

The communication unit 230 of the hybrid stylus 200 may transmit operation mode conversion information by the controller 242 of the hybrid stylus 200 to the touch input device 100.

In this case, the communication unit 160 of the touch input device 100 may receive the operation mode conversion information, and as the operation mode is changed, each of the touch input device 100 and the hybrid stylus 200 may operate in the second mode.

According to the second embodiment, when the hybrid stylus 200 and the touch input device 100 are operating in the first mode as illustrated in FIG. 2B, respectively, and then the touch input device 100 generates the mode change command from the first mode to the second mode and transmits the mode change command to the hybrid stylus 200, the hybrid stylus and the touch input device may operate in the second mode as illustrated in FIG. 2C, respectively.

Specifically, the hybrid stylus 200 may transmit information on the remaining amount of the power to the touch input device 100. In the second embodiment, unlike the first embodiment, in order to generate the mode change command in the touch input device 100, information on the remaining amount of the power of the hybrid stylus 200 may be first received before the mode change command is generated.

Information on the remaining amount of the power may be one obtained by being checked periodically for a predetermined number of times during a predetermined time interval, and information such as a predetermined time interval, a predetermined number, or a period may be preset and stored in a memory (not illustrated).

The communication unit 160 of the touch input device 100 receives information on the remaining amount of the power from the hybrid stylus 200 and the controller 170 may control to operate in the first mode when it is determined that the checked remaining amount of the power is equal to or greater than a predetermined threshold value. In contrast, when it is determined that the checked remaining amount of the power is less than the predetermined threshold value, the controller 170 may control to operate in the second mode. The information on the remaining amount of the power may be separately stored in a memory (not illustrated).

The communication unit 160 may generate operation mode conversion information to the second mode and transmit the operation mode conversion information to the hybrid stylus 200.

The communication unit 230 of the hybrid stylus 200 may receive the operation mode conversion information to the second mode from the touch input device 100. The controller 242 of the hybrid stylus 200 may arrange the position of the switch 243 to the second mode operation unit 241B as illustrated in FIG. 2C based on the operation mode conversion information. As the operation mode is changed, each of the touch input device 100 and the hybrid stylus 200 may operate in the second mode.

According to the third embodiment, unlike the automatic generation of mode conversion information based on the remaining battery capacity information as in the first and second embodiments, the mode conversion information may be manually generated based on a user input.

The button unit 180 of the touch input device 100 may receive the user input for converting/selecting an operation mode with the hybrid stylus 200.

Operation mode conversion information according to the user input may be transmitted to the hybrid stylus 200 through the communication unit 160, and the hybrid stylus 200 may receive the operation mode conversion information through the communication unit 230. In addition, as the operation mode is changed, each of the touch input device 100 and the hybrid stylus 200 may operate in the second mode.

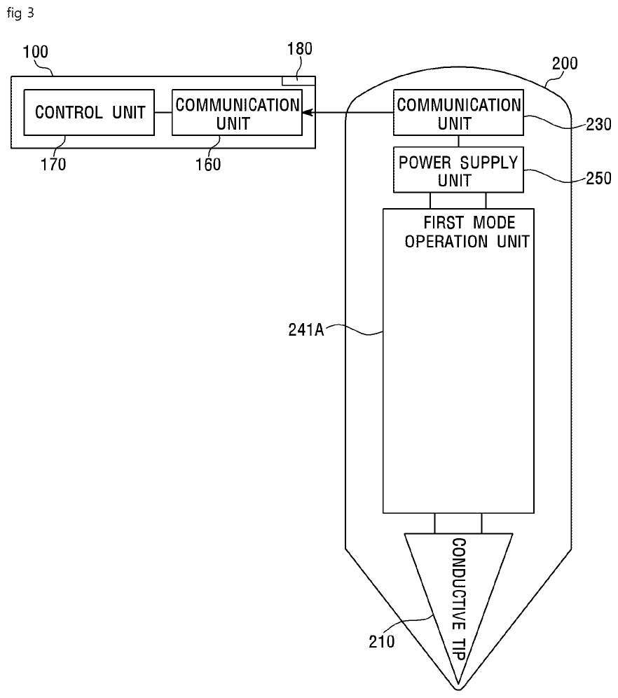

FIG. 3 is a diagram referenced to describe data transmission and reception between the touch input device 100 and the hybrid stylus 200 according to another embodiment of the present invention. In the embodiment of FIG. 3, unlike the embodiment of FIG. 2, when it is determined that the remaining amount of the power is less than or equal to a predetermined threshold value, the existing first mode may be stopped by not switching to another mode but not applying a driving signal to the hybrid stylus 200.

First, as illustrated in FIG. 3, the touch input device 100 according to an embodiment of the present invention may include the communication unit 160, the control unit 170, and the button unit 180. Here, the touch input device 100 of FIG. 3 may be implemented in the same or similar to the touch input device 100 of FIG. 2A. In particular, the communication unit 160 of the touch input device 100 of FIG. 3 may control the operation of the touch input device 100 by receiving state information of the hybrid stylus 200 from the hybrid stylus 200, and may be implemented so that only one-way communication is possible.

Meanwhile, as illustrated in FIG. 3, the hybrid stylus 200 according to another embodiment of the present invention includes the conductive tip 210, the communication unit 230, the power supply unit 250, and the first mode operation unit 241A. Here, the conductive tip 210 and the power supply unit 250 of the hybrid stylus 200 of FIG. 3 may be implemented in the same or similar to the conductive tip 210 and the power supply unit 250 of the hybrid stylus 200 of FIG. 2A.

The communication unit 230 of the hybrid stylus 200 of FIG. 3 may be implemented so that only one-way communication is possible by transmitting status information to the touch input device 100.

In the configuration of the touch input device 100 and/or the hybrid stylus 200 of FIG. 3 described above, all or a part of the configuration may be deleted, another component may be added, or modification may be made thereto.

The first mode operation unit 241A of FIG. 3 may be implemented in the same or similar to the first mode operation unit 241A of FIG. 2A.

Based on such a configuration of the touch input device 100 and the hybrid stylus 200 of FIG. 3, the touch input device 100 and the hybrid stylus 200 may operate as in the following fourth and fifth embodiments depending on whether the touch input device 100 operates by receiving the status information of the hybrid stylus 200 from the hybrid stylus 200 or whether the touch input device 100 receives a user input.

According to the fourth embodiment, when the hybrid stylus 200 and the touch input device 100 are operating in the first mode, respectively, and the information on the remaining amount of the power received from the hybrid stylus 200 by the touch input device 100 is less than or equal to a predetermined threshold value, the hybrid stylus 200 and the touch input device 100 may stop performing the operation in the first mode, respectively.

Specifically, information on a remaining amount of a power of the power supply unit 250 of the hybrid stylus 200 may be transmitted to the touch input device 100 through the communication unit 230. The information on the remaining amount of the power may be periodically checked for a predetermined number of times during a predetermined time interval, and information such as a predetermined time interval, a predetermined number, or a period may be preset and stored in a memory (not illustrated).

The communication unit 160 of the touch input device 100 receives information on the remaining amount of the power from the hybrid stylus 200 and the control unit 170 may control to operate in the first mode when it is determined that the checked remaining amount of the power is equal to or greater than the predetermined threshold value. In contrast, when it is determined that the checked remaining amount of the power is less than the predetermined threshold value, the controller 170 may control such that the driving signal is no longer transmitted to the hybrid stylus 200. That is, the operation of the touch input device 100 and the hybrid stylus 200 in the first mode may be stopped because the driving signal is not transmitted.

The first mode operation unit 241A of the hybrid stylus 200 may stop the operation in the first mode when a driving signal is not input from the touch input device 100, based on information on the remaining amount of the power. When the operation in the first mode is stopped, the hybrid stylus 200 may be recognized as a conductive object such as a finger that does not include a separate circuit.

Depending on the embodiments, it may be configured such that a general touch sensing operation is disabled during the operation in the first mode, and the general touch sensing operation is enabled when the operation in the first mode is stopped. According to such a configuration, while the first mode is in operation, a touch by a finger or a palm is disabled such that a palm rejection function may be implemented.

According to the fifth embodiment, when the hybrid stylus 200 and the touch input device 100 are operating in a first mode, respectively, and the touch input device 100 receives the mode conversion/selection information from a user, each of the hybrid stylus 200 and the touch input device 100 may stop performing an operation in the first mode based on such a manual input. In the case of the fifth embodiment, the separate communication unit 230 and the communication unit 160 may be omitted.

Specifically, the button unit 180 may receive a user input for changing an operation mode with the hybrid stylus 200.

The controller 170 may operate in the first mode or not perform the operation in the first mode based on such a user input. Not performing the operation in the first mode may mean that the driving signal is no longer transmitted to the hybrid stylus 200.

The first mode operation unit 241A of the hybrid stylus 200 may stop the operation in the first mode when the driving signal is no longer input from the touch input device 100. When the operation in the first mode is stopped, the hybrid stylus 200 may be recognized as a conductive object such as a finger that does not include a separate circuit.

Depending on the embodiments, it may be configured such that the general touch sensing operation may be disabled while the operation in the first mode is performed, and the general touch sensing operation may be enabled when the operation in the first mode is stopped. According to such a configuration, while the first mode is in operation, a touch by a finger or a palm is disabled such that a palm rejection function may be implemented.

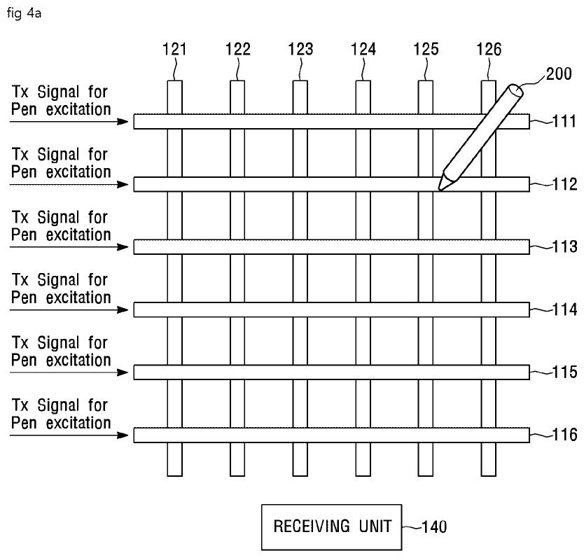

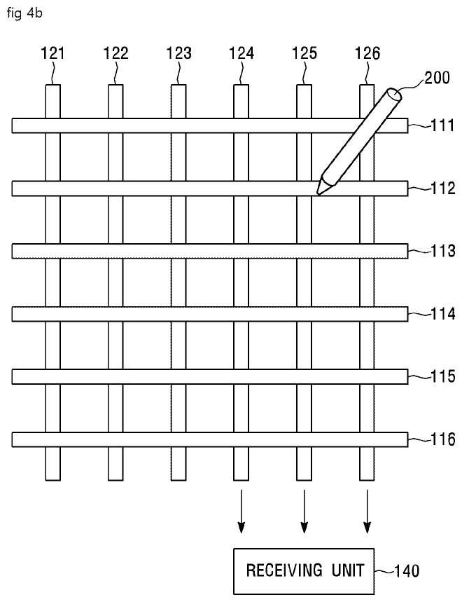

FIGS. 4A and 4B are diagrams for explaining a first mode operation between the hybrid stylus 200 and the touch input device 100 according to an embodiment of the present invention. Specifically, this is an embodiment in which the driving signal of the touch input device 100 is used as a trigger signal for waking up the hybrid stylus 200. As described above, according to the first mode operation according to another embodiment of the present invention, the hybrid stylus 200 may operate without a separate driving signal.

Referring to FIG. 4A, the driving unit 130 (not illustrated) may apply a driving signal (Tx Signal) (specifically, a digital code of the driving signal applied to each first electrode has a different value) to first subgroups 111, 112, and 113 of the first electrode.

In addition, the receiving unit 140 may receive a reception signal from all of the second electrodes 121, 122, 123, 124, 125 and 126 in a state in which the driving signal is applied.

In this case, since the driving signal is used as the trigger signal, the hybrid stylus 200 senses the driving signal and generates a response signal corresponding thereto.

Accordingly, referring to FIG. 4B, a reception signal corresponding to the response signal generated by the hybrid stylus 200 is received by the receiving unit 140.

Meanwhile, the driving signal application and reception signal reception methods of FIGS. 4A and 4B are only examples, and may be variously implemented, such as applying a driving signal to all of the plurality of first electrodes or receiving a reception signal from some of the plurality of second electrodes.

Features, structures, effects, and the like described in the embodiments as above are included in one embodiment of the present invention, and are not necessarily limited to one embodiment. Furthermore, the features, structures, effects, and the like illustrated in each embodiment may be combined or modified for other embodiments by a person having ordinary knowledge in the field to which the embodiments belong. Accordingly, contents related to such combinations and modifications should be interpreted as being included in the scope of the present invention.

In addition, although the description has been described centering on the embodiments as above, these are only illustrative and do not limit the present invention, and those of ordinary skill in the art to which the present invention pertains will appreciate that various modifications and applications not illustrated above may be made thereto without departing from the essential features of the embodiments. For example, each constitutional element specifically illustrated in the embodiment may be modified and embodied. Differences related to these modifications and applications should be construed as being included in the scope of the present invention defined in the appended claims.

### INDUSTRIAL APPLICABILITY

According to the embodiments of the present invention switching from the active stylus mode to the passive stylus mode may be performed automatically by combining the additional function implementation, which is an advantage of the active stylus, and the feature that does not require a separate battery, which is the advantage of the passive stylus.

According to the embodiments of the present invention, even when the battery of the stylus runs out, time and cost may be saved by continuously performing an operation with the touch input device in a switched mode.

[symbol]

1. A hybrid stylus communicating with a touch input device, the hybrid stylus comprising:
a conductive tip that forms a capacitance with at least one of a plurality of electrodes in the touch input device;
a first mode operation unit that operates with the touch input device based on a predetermined power;
a second mode operation unit that operates by using a change in capacitance for at least one of the plurality of electrodes in the touch input device by the conductive tip;
a switch configured to connect the conductive tip to the first mode operation unit or the second mode operation unit;
a power supply unit that provides the predetermined power to the first mode operation unit;
a communication unit that transmits mode conversion information for converting an operation mode of the touch input device to the touch input device; and
a controller that checks the remaining amount of the power to control the switch to connect the conductive tip to the first mode operation unit when a remaining amount of the power is greater than or equal to a predetermined threshold value and to control the switch to connect the conductive tip to the second mode operation unit when the remaining amount of the power is less than the predetermined threshold, and controls the communication unit to transmit the mode conversion information to the touch input device.

2. A touch input device communicating with a hybrid stylus, the touch input device comprising:
a first mode operation unit that operates in a first mode together with the hybrid stylus operating based on a predetermined power;
a second mode operation unit that operates in a second mode by using a change in capacitance for at least one of a plurality of electrodes in the touch input device by the hybrid stylus;
a communication unit that receives mode conversion information from the hybrid stylus; and
a control unit that controls to operate in the first mode or controls to operate in the second mode based on the mode conversion information for operating in the first mode or in the second mode according to a result of checking the remaining amount of the power by the hybrid stylus.

3. A hybrid stylus communicating with a touch input device, the hybrid stylus comprising:
a conductive tip that forms a capacitance with at least one of a plurality of electrodes in the touch input device;
a first mode operation unit that operates in a first mode with the touch input device based on a predetermined power;
a second mode operation unit that operates in a second mode using a change in capacitance for at least one of the plurality of electrodes in the touch input device by the conductive tip;
a switch configured to connect the conductive tip to the first mode operation unit or the second mode operation unit;
a power supply unit that provides the predetermined power to the first mode operation unit;
a communication unit that transmits information on a remaining amount of the power by the hybrid stylus to the touch input device and receives mode conversion information for differently operations according to the information on the remaining amount of the power from the touch input device; and
a controller that arranges a position of the switch to the first mode operation unit or the second mode operation unit based on the mode conversion information.

4. A touch input device communicating with a hybrid stylus, the touch input device comprising:
a first mode operation unit that operates in a first mode together with the hybrid stylus operating based on a predetermined power;
a second mode operation unit that operates in a second mode by using a change in capacitance for at least one of a plurality of electrodes in the touch input device by the hybrid stylus;
a communication unit that receives information on a remaining amount of a power of the hybrid stylus from the hybrid stylus and transmits mode conversion information to the hybrid stylus; and
a control unit that controls to operate in the first mode when the remaining amount of the power is greater than or equal to a predetermined threshold value and to operate in the second mode when the remaining amount of the power is less than the predetermined threshold value according to a result of checking the remaining amount of the power by the hybrid stylus, and controls the communication unit to transmit the mode conversion information for operating in the first mode or the second mode.

5.-12. (canceled)

13. The hybrid stylus of claim 1, wherein the first mode operation unit operates in a synchronization mode in which a response signal is generated in response to a driving signal of the touch input device or an asynchronous mode in which a signal is output without the driving signal of the touch input device.

14. The hybrid stylus of claim 3, wherein the first mode operation unit operates in a synchronization mode in which a response signal is generated in response to a driving signal of the touch input device or an asynchronous mode in which a signal is output without the driving signal of the touch input device.
